(19) United States
(12) Patent Application Publication
(10) Pub. No.: US 2009/0140761 A1
(43) Pub. Date: Jun. 4, 2009

(54) METHOD OF TESTING SEMICONDUCTOR DEVICE

(75) Inventors: Sung-Ok KIM, Chungcheongnam-do (KR); Ae-Yong CHUNG, Chungcheongnam-do (KR); Se-Rae CHO, Chungcheongnam-do (KR); Chul-Min LEE, Chungcheongnam-do (KR); Eun-Seok LEE, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/255,850

(22) Filed: Oct. 22, 2008

(30) Foreign Application Priority Data
Nov. 30, 2007 (KR) 2007-0123820

(51) Int. Cl. G01R 31/26

(52) U.S. Cl. 324/765

(57) ABSTRACT

A method of testing a semiconductor device, which can reduce a period of time for testing a packaged semiconductor chip. First, semiconductor chips to be tested are classified in a lot unit. The semiconductor chips are fist tested in units of lots. The defective semiconductor chips among the semiconductor chips of a predetermined number of lots that are first time tested are collectively retested. First test data regarding the semiconductor chips may be classified and stored for each respective lot. Retest data regarding the semiconductor chips may be classified and stored for each respective lot. Test data regarding the semiconductor chips may be classified and stored into first test data and retest data for each respective lot.

### CROSS-REFERENCE TO RELATED PATENT APPLICATION

This application claims the benefit of Korean Patent Application No. 10-2007-0123820, filed on Nov. 30, 2007, in the Korean Intellectual Property Office, the disclosure of which is incorporated herein in its entirety by reference.

### SUMMARY

The present invention relates to a method of testing a semiconductor device, and more particularly, to a method for reducing a period of time for testing a packaged semiconductor chip.

In a semiconductor test process, electrical characteristics of semiconductor chips manufactured using a method of manufacturing a semiconductor are analyzed, and then the semiconductor chips are classified into non-defective semiconductor chips and defective semiconductor chips in response to the analysis result. After the semiconductor test process, only the non-defective semiconductor chips are provided to a user. The competitive power of a semiconductor apparatus in terms of manufacturing costs is determined according to a yield of non-defective semiconductor chips.

After test and assembly processes are performed with respect to semiconductor chips in a wafer state, before packaged semiconductor chips are provided to a user, the electrical characteristics of the packaged semiconductor chips are analyzed one last time. In this regard, this semiconductor test process is performed on a lot-by-lot basis, and semiconductor chips are classified into non-defective semiconductor chips and defective semiconductor chips in response to the test results.

However, due to an unstable component of a test apparatus, for example, a test socket or a test board, or the critical margin of the electrical characteristics of a semiconductor chip, a non-defective semiconductor chip is often determined as an defective semiconductor chip, and accordingly, the yield of non-defective semiconductor chips is reduced, thereby increasing manufacturing costs.

Embodiments of the present invention provide a method of testing a semiconductor device by using a multi-lot method in which semiconductor chips are first time tested in units of lots of a predetermined number and then semiconductor chips of the lots of the predetermined number, which are determined as defective semiconductor chips, are collectively retested, thereby improving testing efficiency and the yield of the non-defective semiconductor chips.

According to an aspect of the present invention, there is provided a method of testing a semiconductor device with a multi-lot method. First, semiconductor chips to be tested are classified in units of lots. The semiconductor chips are fist time tested in a lot unit. The defective semiconductor chips among the semiconductor chips of a predetermined number of lots that are first time tested are collectively retested.

First test data regarding the semiconductor chips may be classified and stored every respective lot. Retest data regarding the semiconductor chips may be classified and stored every respective lot. Test data regarding the semiconductor chips may be classified and stored into first test data and retest data every respective lot. The method may further comprise classifying the non-defective semiconductor chips into the defective semiconductor chips determined in the first time test and the non-defective semiconductor chips determined in the retest and managing the non-defective semiconductor chips.

According to another aspect of the present invention, there is provided a method of testing a semiconductor device. Semiconductor chips are classified in units of lots. The semiconductor chips may be moved into a test chamber for each respective lot. The semiconductor chips inside the test chamber may be first time tested for each respective lot using a tester. It may be determined whether the tested semiconductor chips are non-defective semiconductor chips or defective semiconductor chips. The defective semiconductor chips may be stored in a tray storing element. It may be determined whether semiconductor chips of a predetermined number of lots are first time tested. As result of the determination, the defective semiconductor chips of the predetermined number of lots, which are stored in the tray storing element, may be moved into the test chamber responsive to the determination of whether the semiconductor chips of the predetermined number of lots are first time tested. The defective semiconductor chips inside the test chamber may be collectively retested using the tester.

### BRIEF DESCRIPTION OF THE DRAWINGS

The above and other features and advantages of the present invention will become more apparent by describing in detail exemplary embodiments thereof with reference to the attached drawings in which:

FIG. 1 is a structural view of a test apparatus for testing a semiconductor device, according to an embodiment of the present invention;

FIG. 2 is a flowchart of a method of testing a semiconductor device, according to an embodiment of the present invention;

FIG. 3 illustrates a method of storing defective semiconductor chips into trays in a tray storing element, according to an embodiment of the present invention;

FIGS. 4A and 4B respectively illustrate a method in which semiconductor chips of lots of a predetermined number are first time tested and then defective semiconductor chips are collectively retested, and a method in which semiconductor chips are first time tested and then retested for each respective lot; and

FIG. 5 illustrates a method of storing test data, according to an embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. The same reference numerals in the drawings denote the same element.

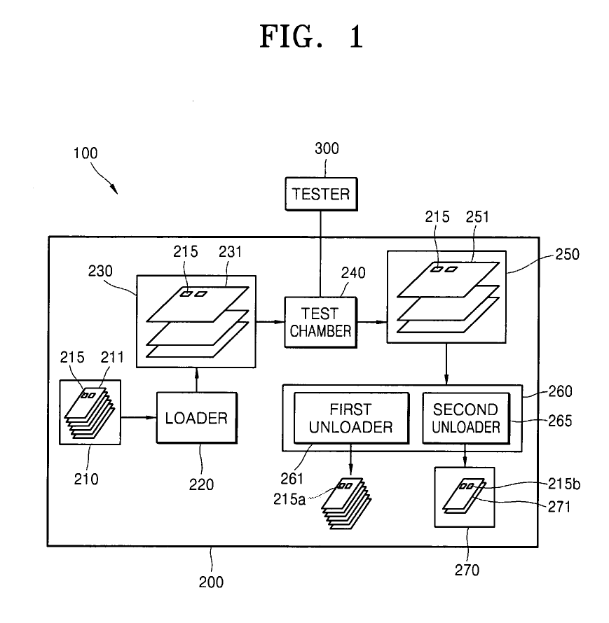

FIG. 1 is a structural view of a test apparatus 100 for testing a semiconductor device, according to an embodiment of the present invention. Referring to FIG. 1, the test apparatus 100 includes a handler 200 and a tester 300. The handler 200 includes a first tray storing element 210 and a second tray storing element 270, wherein the first tray storing element 210 stores customer trays 211 on which semiconductor chips 215 that are to be first tested are arranged and the second tray storing element 270 stores trays 271 on which defective semiconductor chips 215b that are to be retested are arranged.

The handler 200 further includes a loader 220 and an unloader 260, wherein the loader 220 moves the semiconductor chips 215 of the first tray storing element 210 into a test chamber 240 and the unloader 260 takes out non-defective chips 215a and defective semiconductor chips 215b that are tested from the test chamber 240. The unloader 260 includes a first unloader 261 and a second unloader 265, wherein the first unloader 261 takes the non-defective semiconductor chips 215a among the semiconductor chips 215a and 215b that are tested from the test chamber 240 out of the handler 200, and the second unloader 265 takes the defective semiconductor chips 215b among the non-defective and defective semiconductor chips 215a and 215b that are tested from the test chamber 240 to the second tray storing element 270. In addition, the unloader 260 may take definitely-defective semiconductor chips (not shown) out of the handler 200 from the test chamber 240.

The handler 200 further includes a soak chamber 230, the test chamber 240, and a defrost chamber 250, wherein the soak chamber 230 may change the temperature of the semiconductor chips 215 from a room temperature to a test temperature required in the test chamber 240. The test chamber 240 is loaded with the semiconductor chips 215 whose temperature is changed to the test temperature in the soak chamber 230 so that the semiconductor chips 215 may be tested by the tester 300. The defrost chamber 250 may change the temperature of the semiconductor chips 215 that are tested and taken out from the test chamber 240 from the test temperature back to the room temperature.

The semiconductor chips 215 that are classified on a lot-by-lot basis may be packaged semiconductor chips on which a wafer test process and an assembly process are completed. The semiconductor chips 215 may be bound up in a predetermined unit so as to be moved in order to ensure the stability of movement between processes. In this regard, a customer tray 211 may be used as a device for moving the semiconductor chips 215. The semiconductor chips 215 are bound up in a predetermined unit and moved so as to be tested in the test chamber 240. In this regard, test trays 231 and 251 may be used as devices for transferring the semiconductor chips 215.

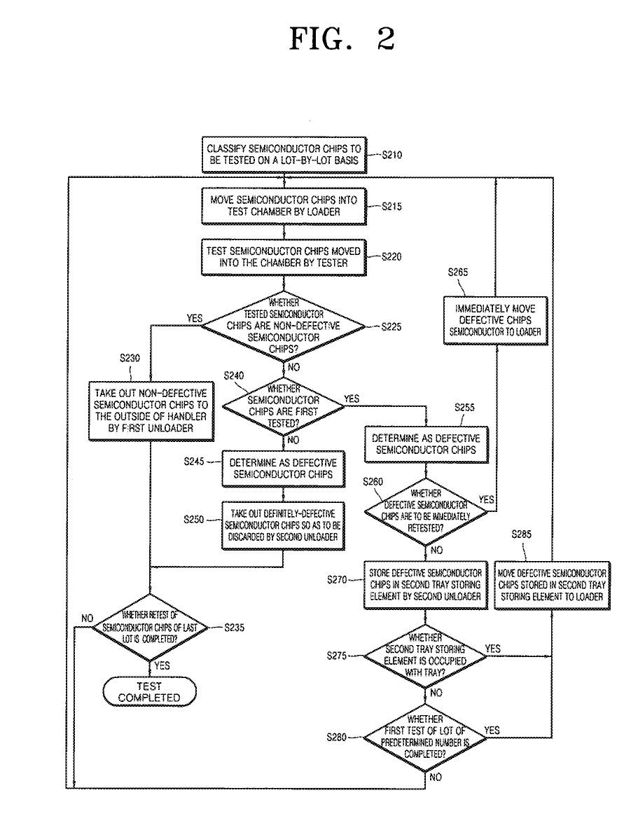

FIG. 2 is a flowchart of a method of testing a semiconductor device, according to an embodiment of the present invention. In the current embodiment, the semiconductor chips 215 of four lots may each be sequentially tested in a first test, and then the defective semiconductor chips 215b of the four lots, which are determined in the first test, are collectively retested.

Referring to FIGS. 1 and 2, the semiconductor chips 215 to be tested may be classified on a lot-by-lot basis and then stored in the first tray storing element 210 (operation S210). The semiconductor chips 215 of a plurality of lots can be stored in the first tray storing element 210 in units of the customer tray. The semiconductor chips 215 are arranged in units of the customer tray so as to be stored in the customer tray of the first tray storing element 210. The semiconductor chips 215 of a first lot LOT #1, among the semiconductor chips 215 of the plurality of lots stored in the first tray storing element 210, are moved into the test chamber 240 by the loader 220 in units of the customer tray (operation S215).

The semiconductor chips 215 may be moved into the soak chamber 230 prior to being moved into the test chamber 240. The semiconductor chips 215 of the first tray storing element 210 may be moved into the soak chamber 230 by the loader 220 in units of the customer tray. The soak chamber 230 changes the temperature of the semiconductor chips 215 moved from the first tray storing element 210 from room temperature to the test temperature required in the test chamber 240. The semiconductor chips 215 inside the soak chamber 230 are arranged in units of the test tray and have the test temperature suitable for the test. The temperature of the semiconductor chips 215 is changed to the test temperature in the soak chamber 230 before testing the semiconductor chips 215 in the test chamber 240 in order to reduce a period of time for testing. This may be contrasted with the case where the temperature of the semiconductor chips 215 is changed in the test chamber 240 and then is tested.

The semiconductor chips 215 inside the soak chamber 230 may be moved into the test chamber 240 in units of the test tray. The semiconductor chips 215 which are moved into the test chamber 240 are tested by the tester 300 (operation S220). At this time, the tester 300 may test the semiconductor chips 215 in parallel. The semiconductor chips 215 tested in the test chamber 240 may be moved into the defrost chamber 250. Furthermore, the semiconductor chips 215 inside the test chamber 240 may be moved into the defrost chamber 250 in units of the test tray. The defrost chamber 250 is used for restoring the temperature of the semiconductor chips 215, which is changed to the test temperature for the test, then back to room temperature. By restoring the temperature of the semiconductor chips 215 that are tested back to room temperature using the defrost chamber 250, a period of time for performing the test can be reduced.

After semiconductor chips 215 are tested in the test chamber 240, the tested semiconductor chips 215 are checked to discover whether they are the non-defective semiconductor chips 215a or not (operation S225). In operation S225, the non-defective semiconductor chips 215a among the semiconductor chips 215 are taken out of the handler 200 by the first unloader 261 (operation S230). The non-defective semiconductor chips 215a may be taken out in units of the customer tray.

After the non-defective semiconductor chips 215a are taken out of the handler 200, it is checked whether the retest of the semiconductor chips 215 of the last lot is completed in operation S235. When the retest of the semiconductor chips 215 of the last lot is determined to be completed in operation S235, the test is completed. When the retest of the semiconductor chips 215 of the last lot is determined not to be completed in operation S235, operation S215 is again performed. The semiconductor chips 215 of next lots LOT #2, LOT #3, etc., which are to be tested, are moved from the first tray storing element 210 into the test chamber 240 by the loader 220, and then the test proceeds to be performed.

When the semiconductor chips 215 that are tested are determined not to be the non-defective semiconductor chips 215a in operation S225, it is checked whether the semiconductor chips 215 are first time tested (operation S240), i.e., tested only once so far. When the semiconductor chips 215 that are tested are determined not to be first time tested in operation S240, i.e., when the semiconductor chips 215 that are tested are determined to have been retested, the semiconductor chips 215 that have been retested are determined as definitely-defective semiconductor chips (not shown) (operation S245). The definitely-defective semiconductor chips are taken out of the handler 200 by the second unloader 265 and are discarded (operation S250). Next, it is checked whether the retest of the semiconductor chips 215 of the last lot is completed in operation S235. When the retest of the semiconductor chips 215 of the last lot is determined to be performed in operation S235, the test is completed. When the retest of the semiconductor chips 215 of the last lot is determined not to be performed in operation S235, operation S215 is again performed. The semiconductor chips 215 of next lots LOT #2, LOT #3, etc., which are to be tested, are moved from the first tray storing element 210 into the test chamber 240 by the loader 220, and then the test proceeds to be performed.

Referring back to operation S240, when the semiconductor chips 215 that are tested are determined to be first time tested, the semiconductor chips 215 that are tested are determined as the defective semiconductor chips 215b (operation S255). Next, it is checked whether the defective semiconductor chips 215b need to immediately be retested (operation S260). For example, the defective semiconductor chips 215b may immediately be retested when a failure rate difference between lots is higher than a predetermined amount or otherwise determined be have a large difference. For example, a failure rate difference between lots may be large when the failure rate is higher than an average failure rate by a predetermined amount. When the failure rate difference between lots is large, the semiconductor chips 215 and processes are analyzed so as to determine the reason for the failure. By addressing and removing the reason for the failure, based on results of the analysis, additional failures can be prevented.

When it is determined that the defective semiconductor chips 215b need to immediately be retested in operation S260, the defective semiconductor chips 215b are taken out of the defrost chamber 250 by the second unloader 265, and the defective semiconductor chips 215b are immediately moved to the loader 220 by a transfer device (not shown) (operation S265). The 10 loader 220 moves the defective semiconductor chips 215b into the test chamber 240, and the defective semiconductor chips 215b are retested in the test chamber 240 by the tester 300 in the same manner as the first test. Thus, when the retest is performed per four lots, the defective semiconductor chips 215b may immediately be retested even though the first test of the semiconductor chips 215 of the fourth lot is not completed. The need to immediately retest may be based on an emergency or for efficiency reasons, among other possibilities.

When the defective semiconductor chips 215b are determined not to need immediate retesting in operation S260, the defective semiconductor chips 215b may be stored in the second tray storing element 270 by the second unloader 265 (operation S270). The defective semiconductor chips 215b may be stored in the second tray storing element 270 in the form of the customer tray 211 and may be classified on a lot-by-lot basis.

Next, it is checked whether the trays 271 on which the defective semiconductor chips 215b are arranged are completely occupied (operation S275). When the second tray storing element 270 is determined to be completely occupied with the trays 271 in operation S275, the defective semiconductor chips 215b stored in the second tray storing element 270 are moved to the loader 220 by the transfer device, even though the first test of the semiconductor chips 215 from lots of a predetermined number is not completed (operation S285). Next, referring back to operation S215, the loader 220 moves the defective semiconductor chips 215b into the test chamber 240, and then the defective semiconductor chips 215b are retested. When the retest is performed for every four lots, the second tray storing element 270 may be completely occupied by the trays 271 if many defective semiconductor chips 215b are found. At this time, the retest of the defective semiconductor chips 215b of the second tray storing element 270 may immediately be performed, even though the first test of the semiconductor chips 215 of the fourth lot is not completed.

When the second tray storing element 270 is determined to be not completely occupied by the trays 271 in operation S275, it is checked whether the first test of the semiconductor chips 215 of lots of a predetermined number (e.g., four lots) is completed (operation S280). For example, if the retest is assumed to be performed per four lots, when the first test of the semiconductor chips 215 of the fourth lot is not completed, operation S215 is again performed. In operation S215, the semiconductor chips 215 of the next lot, which are stored in the first tray storing element 210, are moved into the test chamber 240 by the loader 220, and then the first test is performed with respect to the semiconductor chips 215 of the next lot by using the above-described method.

In operation S280, when the first test of the semiconductor chips 215 of a predetermined number of lots is completed, for example, when the first test of the semiconductor chips 215 of the fourth lot is completed, the method proceeds to operation S285, and then returns to operations S215, S220, S225, S230, S235, S240, S245 and S250, and so forth. Specifically, the trays 271 stored in the second tray storing element 270 are moved to the loader 220 in a first in last out (FILO) order. The loader 220 moves the defective semiconductor chips 215b, which are moved from the second tray storing element 270, into the test chamber 240, and then the defective semiconductor chips 215b are retested.

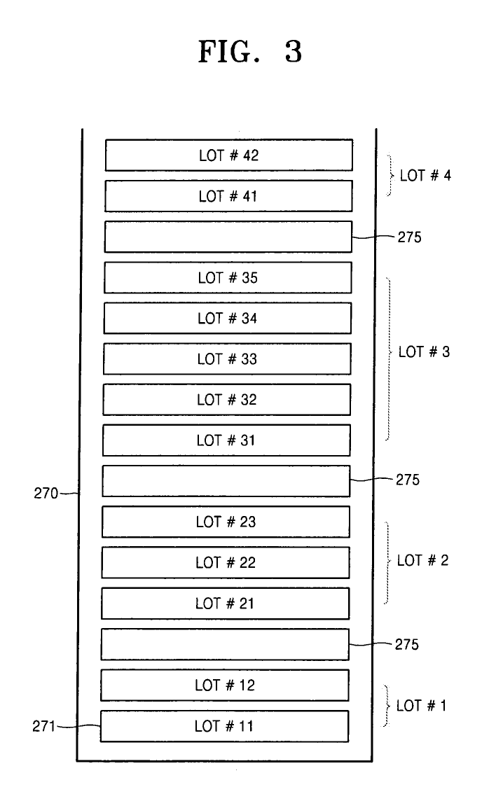

FIG. 3 illustrates a method of storing the defective semiconductor chips 215b into the trays 271 of the second tray storing element 270, according to an embodiment of the present invention. Referring to FIG. 3, the defective semiconductor chips 215b are stored in the second tray storing element 270 for each respective lot. While trays 271 are identified as LOT #11, LOT #12, LOT #21, and so forth, trays 271 can also be identified as TRAY #11, TRAY #12, TRAY #21, and so forth, among other possibilities. Specifically, trays LOT #11 and LOT #12 on which the defective semiconductor chips 215b are arranged are sequentially stacked, wherein the defective semiconductor chips 215b are tested among the semiconductor chips 215 of the first lot LOT #1. Then, trays LOT #21 through LOT #23 on which the defective semiconductor chips 215b are arranged are sequentially stacked, wherein the defective semiconductor chips 215b are tested among the semiconductor chips 215 of the second lot LOT #2. Moreover, trays LOT #31 through LOT #35 on which the defective semiconductor chips 215b are arranged are sequentially stacked, wherein the defective semiconductor chips 215b are tested among the semiconductor chips 215 of the third lot LOT #3. In addition, trays LOT #41 and LOT #42 on which the defective semiconductor chips 215b are arranged are sequentially stacked, wherein the defective semiconductor chips 215b are tested among the semiconductor chips 215 of the fourth lot LOT #4.

In the meantime, when the defective semiconductor chips 215b are stored in the second tray storing element 270 for each respective lot, one or more empty trays 275 may be inserted between the trays 271 of each lot in order to distinguish the defective semiconductor chips 215b of each lot. The empty tray 275 may include a customer tray. For example, the empty trays 275 may be inserted between the tray LOT #12 on which the defective semiconductor chips 215b of the first lot LOT #1 are arranged and the tray LOT #21 on which the defective semiconductor chips 215b of the second lot LOT #2 are arranged, and between the tray LOT #23 on which the defective semiconductor chips 215b of the second lot LOT #2 are arranged and the tray LOT #31 on which the defective semiconductor chips 215b of the third lot LOT #3 are arranged. In addition, the empty trays 275 may be inserted between the tray LOT #35 on which the defective semiconductor chips 215b of the third lot LOT #3 are arranged and the tray LOT #41 on which the defective semiconductor chips 215b of the fourth lot LOT #4 are arranged. Here, the empty tray 275 is a tray on which there are no semiconductor chips 215, 215a and 215b.

The trays 271 where the defective semiconductor chips 215b of the first lot LOT #1 to the fourth lot LOT #4 are arranged are sequentially stored in the second tray storing element 270. The trays 271 stored in the second tray storing element 270 are sequentially moved to the loader 220, wherein the defective semiconductor chips 215b of the fourth lot LOT #4 to the first lot LOT #1 are arranged on the trays 271. That is, the trays 271 stored in the second tray storing element 270 are moved to the loader 220 in a FILO order.

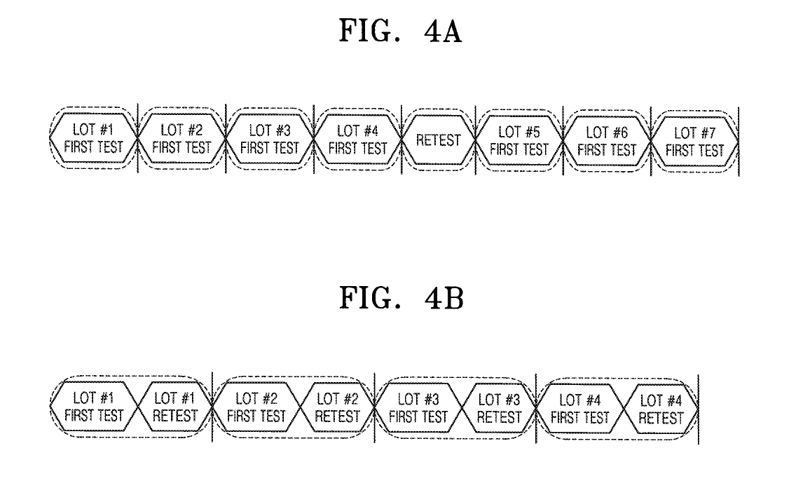

FIGS. 4A and 4B respectively illustrate a method in which semiconductor chips of lots of a predetermined number are first time tested and then defective semiconductor chips are collectively retested, and a method in which semiconductor chips are first time tested and then retested at each respective lot. Referring to FIGS. 4A and 4B, when the semiconductor chips are retested per lots of a predetermined number of lots (e.g., per four lots), the semiconductor chips of four lots LOT #1 through LOT #4 are sequentially tested in a first test, and then defective semiconductor chips of the four lots LOT #1 through LOT #4 are collectively retested. Thus, only one retest process may be performed.

On the other hand, when the semiconductor chips are first time tested and then retested for each respective lot, the semiconductor chips of four lots LOT #1 through LOT #4 are first time tested, and then defective semiconductor chips of the four lots LOT #1 through LOT #4 are separately retested. Thus, four retest processes may be performed. Accordingly, when the defective semiconductor chips are collectively retested for a predetermined number of lots, a period of time for the test can be reduced and the retest of the defective semiconductor chips can be efficiently performed compared with the case where the retest of the defective semiconductor chips is performed for each respective lot. When the number of lots to be tested is increased, a period of time for performing the test can be more effectively reduced.

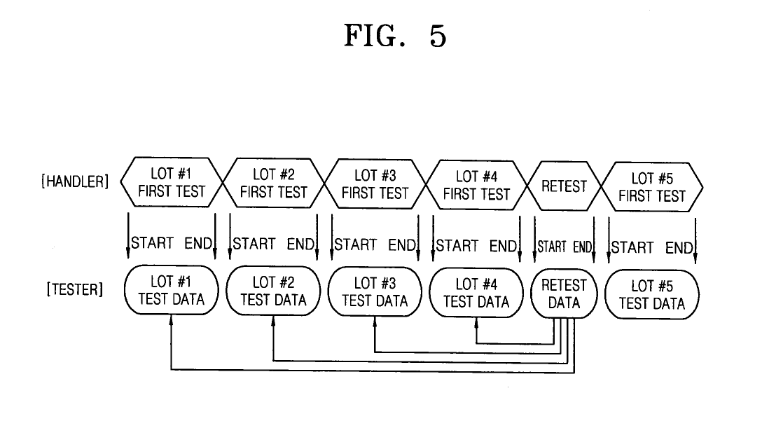

FIG. 5 illustrates a method of storing test data, according to an embodiment of the present invention. Referring to FIG. 5, when the first test is performed with respect to lots LOT #1 through LOT #4 by the handler 200 (see FIG. 1), the tester 300 (see FIG. 1) stores the data regarding the lots LOT #1 through LOT #4. The tester 300 may store data regarding the first test of the lots LOT #1 through LOT #4 for each of the respective lots LOT #1 though LOT #4. When the retest of the lots LOT #1 through LOT #4 is collectively performed, the tester 300 may store data regarding the retest of the lots LOT #1 through LOT #4 for each of the respective lots LOT #1 through LOT #4. Thus, the tester 300 can store the test data for each respective lot, and may classify the test data regarding each lot into first test data and retest data.

According to the above embodiments, in a method of testing a semiconductor device, semiconductor chips are tested using a multi-lot method in which packaged semiconductor chips are first time tested in units of lots of a predetermined number and then defective semiconductor chips among the semiconductor chips are collectively retested. Thus, by retesting the semiconductor chips that are determined as the defective semiconductor chips in the first test, non-defective semiconductor chips can be checked, thereby improving the yield of the non-defective semiconductor chips. Moreover, by retesting the defective semiconductor chips by using the multi-lot method, testing efficiency can be improved, and a period of time for performing the test can be reduced. In addition, data not only can be classified for each respective lot but also can be classified into the first test data and the retest data so as to be more effectively managed. By classifying and managing non-defective semiconductor chips into non-defective semiconductor chips determined in the first test and non-defective semiconductor chips determined in the retest, stable products can be achieved.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A method for testing a semiconductor device, the method comprising:
classifying semiconductor chips by lot;
testing the semiconductor chips in a first test to classify into non-defective semiconductor chips and defective semiconductor chips;
collectively retesting the defective semiconductor chips among the semiconductor chips that are tested in the first test, for a predetermined number of lots; and
after collectively retesting the defective semiconductor chips, classifying the defective semiconductor chips into non-defective semiconductor chips and definitely-defective semiconductor chips.

2. The method of claim 1, wherein first test data regarding the semiconductor chips are classified and stored for each respective lot.

3. The method of claim 2, wherein retest data regarding the semiconductor chips are classified and stored for each respective lot.

4. The method of claim 1, wherein test data regarding the semiconductor chips are classified into first test data and retest data so as to be stored for each respective lot.

5. The method of claim 1, further comprising classifying the non-defective semiconductor chips into the non-defective semiconductor chips determined in the first test and the non-defective semiconductor chips determined in the retest.

6. A method for testing a semiconductor device, the method comprising:
classifying semiconductor chips in units of lots;
moving each respective lot of semiconductor chips into a test chamber;
first time testing the semiconductor chips inside the test chamber using a tester;
determining whether the tested semiconductor chips are non-defective semiconductor chips or defective semiconductor chips;
storing the defective semiconductor chips in a tray storing element;
determining whether semiconductor chips of a predetermined number of lots are first time tested;
moving the defective semiconductor chips of the predetermined number of lots, which are stored in the tray storing element, into the test chamber responsive to the determination of whether the semiconductor chips of the predetermined number of lots are first time tested; and
collectively retesting the defective semiconductor chips of the predetermined number of lots inside the test chamber using the tester.

7. The method of claim 6, wherein determining whether the tested semiconductor chips are non-defective semiconductor chips or defective semiconductor chips comprises:
carrying the non-defective semiconductor chips to the outside when the tested semiconductor chips are the non-defective semiconductor chips;
determining whether the semiconductor chips are first time tested when the tested semiconductor chips are not the non-defective semiconductor chips;
determining the semiconductor chips as the definitely-defective semiconductor chips when the semiconductor chips are not first time tested;
carrying the definitely-defective semiconductor chips to the outside to be discarded; and
determining the semiconductor chips as the defective semiconductor chips when the semiconductor chips are first time tested.

8. The method of claim 7 further comprising:
after the non-defective semiconductor chips or the definitely-defective semiconductor chips are carried to the outside,
determining whether the retesting of a last of the predetermined lots of semiconductor chips is completed; and
when retesting of the semiconductor chips of the last lot is determined not to be completed, moving the semiconductor chips of a next lot into the test chamber to perform one of a) the first time test and b) the retest.

9. The method of claim 6, further comprising:
prior to storing the non-defective semiconductor chips in the tray storing element,
determining whether the defective semiconductor chips are to immediately be retested; and
moving the defective semiconductor chips into the test chamber and immediately retesting the defective semiconductor chips responsive to the determination.

10. The method of claim 9, wherein the defective semiconductor chips are determined to immediately be retested when a failure rate difference between the semiconductor chips of a previous lot and the semiconductor chips of a current lot is higher than a predetermined amount.

11. The method of claim 6, further comprising:
prior to determining whether the semiconductor chips of the predetermined number of lots are first time tested,
determining whether the tray storing element is completely occupied; and
moving the semiconductor chips of the tray storing element into the test chamber and retesting the semiconductor chips when the tray storing element is determined to be completely occupied.

12. The method of claim 6 further comprising:
after classifying the semiconductor chips in units of lots, and prior to moving each respective lot of semiconductor chips into the test chamber,
changing a temperature of the semiconductor chips to be tested from a room temperature to a test temperature.

13. The method of claim 12 further comprising:
after testing the semiconductor chips and removing the semiconductor chips from the test chamber, and prior to determining whether the tested semiconductor chips are the non-defective semiconductor chips,
changing the temperature of the tested semiconductor chips from the test temperature to the room temperature.

14. The method of claim 6, wherein the semiconductor chips to be tested are moved in units of customer trays.

15. The method of claim 6, wherein the semiconductor chips inside the test chamber are moved in units of customer trays.

16. The method of claim 6, wherein the defective semiconductor chips are arranged in trays for each respective lot and stored in the tray storing element.

17. The method of claim 16, further comprising inserting empty trays between trays of different lots on which the defective semiconductor chips are arranged.

18. The method of claim 6, wherein when the defective semiconductor chips stored in the tray storing element are retested, the defective semiconductor chips of a lot on which a first test is performed later than semiconductor chips of another lot are retested prior to the semiconductor chips of the another lot.

19. A method for testing a semiconductor device, the method comprising:
classifying semiconductor chips in units of lots;
moving each respective lot of semiconductor chips into a test chamber;
first time testing the semiconductor chips inside the test chamber using a tester;
determining whether the tested semiconductor chips are non-defective semiconductor chips or defective semiconductor chips;
determining whether semiconductor chips of a predetermined number of lots are first time tested;
moving the defective semiconductor chips of the predetermined number of lots into the test chamber responsive to the determination of whether the semiconductor chips of the predetermined number of lots are first time tested; and
collectively retesting the defective semiconductor chips of the predetermined number of lots inside the test chamber using the tester,
wherein the test data of the semiconductor chips is classified for each respective lot and are stored in the tester.

20. The method of claim 19, wherein the test data of the semiconductor chips is classified into first test data and retest data.
